(19) United States
(12) Patent Application Publication
(10) Pub. No.: US 2008/0259555 A1
(43) Pub. Date: Oct. 23, 2008

(54) MODULAR BLADE SERVER

(75) Inventors: Andreas V. Bechtolsheim, Palo Alto, CA (US); Jorge E. Lach, Lexington, MA (US); Paul G. Phillips, Westborough, MA (US)

Correspondence Address: OSHA LIANG L.L.P./SUN, 1221 MCKINNEY, SUITE 2800, HOUSTON, TX, 77010, US

(73) Assignee: SUN MICROSYSTEMS, INC., Santa Clara, CA (US)

(21) Appl. No.: 12/101,727

(22) Filed: Apr. 11, 2008

Related U.S. Application Data
(63) Continuation of application No. PCT/US2007/000957, filed on Jan. 12, 2007.
(60) Provisional application No. 60/759,087, filed on Jan. 13, 2006.

(51) Int. Cl. H05K 7/10

(52) U.S. Cl. 361/686

(57) ABSTRACT

A blade server includes a chassis; a first plurality of bays in the chassis, wherein the first plurality of bays is adapted to receive and at least partially house a plurality of CPU modules, and wherein the first plurality of bays is accessible through a first side of the chassis; a second plurality of bays in the chassis, wherein the second plurality of bays is adapted to receive and at least partially house a plurality of PCI-Express modules, and wherein the second plurality of bays is accessible through a second side of the chassis; and a midplane board arranged to pass a PCI-Express signal between at least one of the plurality of CPU modules and at least one of the plurality of PCI-Express modules.

### BACKGROUND

As generally referred to in the art, a “server” is a computing device that is configured to perform operations for one or more other computing devices connected over a network. For an entity that requires computing infrastructure for handling relatively large amounts of network data, it is desirable to use servers that are designed to promote organizational/space efficiency and operational performance. In this regard, some servers are designed to be arranged in a “rack,” whereby the rack (or “cabinet”) houses numerous servers that are arranged vertically one on top of another (however, not necessarily in contact with one another). Such a server is generally referred to in the art as a “rackmount” server.

Another type of server is designed to have a chassis for housing a number of individual circuit boards, each having one or more processors, memory, storage, and network connections, but sharing, for example, a power supply and air-cooling resources (e.g., fans) of the chassis. Such a server is generally referred to in the art as a “blade” server, where each individual circuit board is generally referred to in the art as a “blade.” Those skilled in the art will recognize that one of the aims in using a blade server is to be able to place many blades in a single chassis, thereby compacting increased computing power in an area less than that which would be necessary were each of the blades individually housed.

Those skilled in the art will note that a blade in a blade server may be switched out during operation of the blade server, i.e., the blade may be “hot-swappable.” Now referring to FIG. 1, when a blade 10 is actually placed in a blade server 12, the blade 10 is connected to a midplane board 14 that is connected to one or more other blades (shown, but not labeled) in the blade server 12. The midplane board 14 is connected to network input/output (“I/O”) communication modules 16 accessible by the blades connected to the midplane board 14. The network I/O modules 16 facilitate communication between the blades and one or more networks (e.g., the Internet) connected to the blade server 12. Accordingly, in such a case, those skilled in the art will note that network I/O occurs over the midplane board 14.

Those skilled in the art will note that typical blade servers support I/O expansion for Fibre Channel, Infiniband, etc. on the blade itself and then route these signals over the midplane to Fibre Channel, Infiniband, and/or Ethernet switches connected to the same midplane that aggregates these network interfaces before connecting to external networks. The difficulty with this approach is that each blade must be configured with the appropriate I/O adaptors, which make them not universal. Thus, the chassis must be configured with the appropriate switches, which may result in adding significant cost and introducing additional network management points in an enterprise network.

### SUMMARY

According to one aspect of one or more embodiments of the present invention, an apparatus comprises: a chassis; a first plurality of bays in the chassis, where the first plurality of bays is adapted to receive and at least partially house a plurality of CPU modules, and where the first plurality of bays is accessible through a first side of the chassis; a second plurality of bays in the chassis, where the second plurality of bays is adapted to receive and at least partially house a plurality of PCI-Express modules, and where the second plurality of bays is accessible through a second side of the chassis; and a printed circuit board (PCB) arranged to pass a PCI-Express signal between at least one of the plurality of CPU modules and at least one of the plurality of PCI-Express modules.

According to another aspect of one or more embodiments of the present invention, a blade server comprises: a plurality of blades retained within a chassis of the blade server, the plurality of blades being accessible through a first side of the chassis; a printed circuit board (PCB) arranged to pass PCI-Express signals; a first PCI-Express connector arranged to connect at least one of the plurality of blades and the PCB; a plurality of PCI-Express modules retained in the chassis, the PCI-Express modules being accessible through a second side of the chassis; and a second PCI-Express connector arranged to connect the PCB and at least one of the plurality of PCI-Express modules.

According to another aspect of one or more embodiments of the present invention, a method of performing computing operations comprises: receiving from a network a request to perform an operation; performing the operation in response to the receiving; and passing a PCI-Express signal over a printed circuit board (PCB) of a blade server dependent on the performing; and passing the PCI-Express signal from the PCB to a PCI-Express module of the blade server connected to the network.

According to another aspect of one or more embodiments of the present invention, a blade server comprises: a plurality of blades retained within a chassis of the blade server, where the plurality of blades is accessible through a first side of the chassis; a printed circuit board (PCB) operatively connected to the plurality of blades and arranged to pass PCI-Express signals; and a Network Express module operatively connected to the PCB and retained in the chassis, where the Network Express module is accessible through a second side of the chassis, where the plurality of blades is operatively connectable to the Network Express module.

According to another aspect of one or more embodiments of the present invention, a blade server comprises: a plurality of blades; and a plurality of redundant fans arranged to cool the plurality of blades, where the plurality of redundant fans is positioned along a side of a chassis of the blade server, and where an air flow zone for cooling the plurality of blades is separate from an air flow zone for at least one of a power supply and I/O of the blade server.

Other aspects of the present invention will be apparent from the following description and the appended claims.

### BRIEF DESCRIPTION OF DRAWINGS

FIG. 1 shows a typical blade server

FIG. 2A shows a front side view of a blade server in accordance with an embodiment of the present invention.

FIG. 2B shows a rear side view of a blade server in accordance with an embodiment of the present invention.

FIG. 2C shows a side view of a blade server in accordance with an embodiment of the present invention.

FIG. 3 shows a front side view of a blade server in accordance with an embodiment of the present invention.

FIG. 4 shows a rear side view of a blade server in accordance with an embodiment of the present invention.

FIG. 5 shows an exemplary Sun Blade Modular system chassis front view.

FIG. 6 shows an exemplary Sun Blade Modular system Chassis side view.

FIG. 7 shows the arrangement of the PCI-express modules relative to each CPU blade.

FIG. 8 shows an exemplary Sun Blade Modular system Dual processor blade configuration.

FIG. 9 shows an exemplary Sun Blade Modular system Quad processor blade configuration.

FIG. 10 shows an exemplary Sun Blade Modular system blade physical specification.

FIGS. 11-14 show an exemplary Sun Blade 8000 Modular system chassis.

FIG. 15 shows an exemplary Sun Blade 8000 Modular system chassis configuration side-view.

FIG. 16 shows various exemplary embodiments of the Sun Blade 8000 Modular system blade server interconnect of internal components with each other.

FIG. 17 shows a schematic configuration of the exemplary blade server I/O distribution.

FIG. 18 shows exemplary Sun Blade 8000 Modular system network expansion modules.

FIG. 19 shows the topology of the management Ethernet network.

FIG. 20 shows some exemplary embodiments of NEM (NM) I/O architectures.

FIG. 21 shows each blade directly connected to two EMs, and to four NMs.

FIG. 22 shows the mechanical layout (midplane view) of the midplane connector.

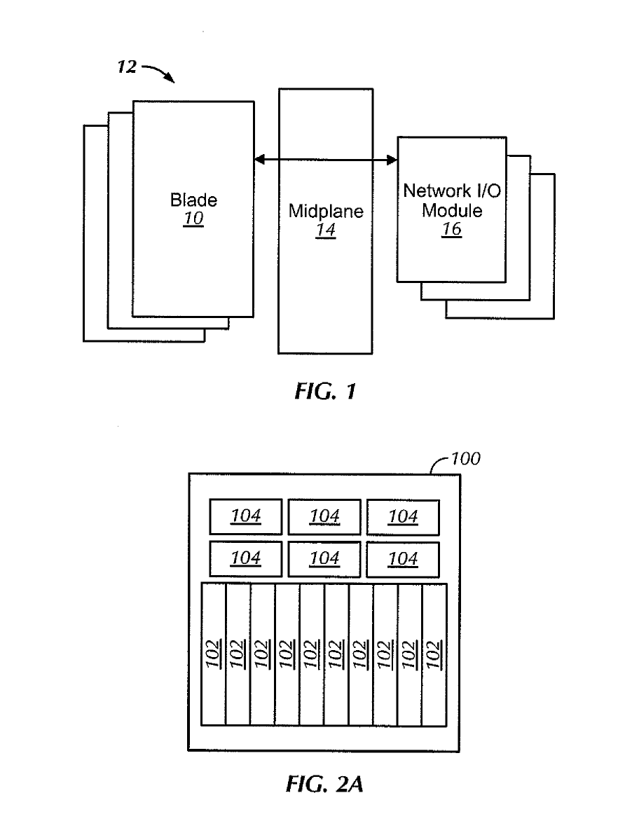

### DETAILED DESCRIPTION

Specific embodiments of the present invention will now be described in detail with reference to the accompanying figures. Like elements in the various figures are denoted by like reference numerals for consistency. Further, in the following detailed description of embodiments of the present invention, numerous specific details are set forth in order to provide a more thorough understanding of the present invention. In other instances, well-known features have not been described in detail to avoid obscuring the description of embodiments of the present invention.

Generally, embodiments of the present invention relate to a blade server. More particularly, one or more embodiments of the present invention rely on the use of PCI-Express technology. Those skilled in the art will note that PCI-Express technology relates to an I/O interface that implements a high-speed serial interconnect having higher performance and occupying less space than an I/O interface implemented using traditional PCI (peripheral component interconnect). In one or more embodiments of the present invention, PCI-Express signals may be used to connect the blades of a blade server to the I/O expansion modules of the blade server, thereby decoupling the need for I/O expansion from the blades. Accordingly, this removes the need for configuring I/O expansion on a per blade basis and avoids the need to integrate network switches in the blade server.

In one or more embodiments of the present invention, a plurality of blades (also referred to herein as “CPU modules”) may be inserted into a front of a chassis and connected to a midplane board, where the midplane board is arranged to pass PCI-Express signals between the CPU modules and a plurality of PCI-E Express modules that may be connected to the midplane board via insertion into a rear of the chassis.

In one or more embodiments of the present invention, Network Express modules may be associated with all bladed in a chassis of a blade server. This enables I/O aggregation and virtualization across all blades. Using PCI-Express as the interface to the blades. Those skilled in the art will note such a technique is relatively simpler than with typical network interfaces.

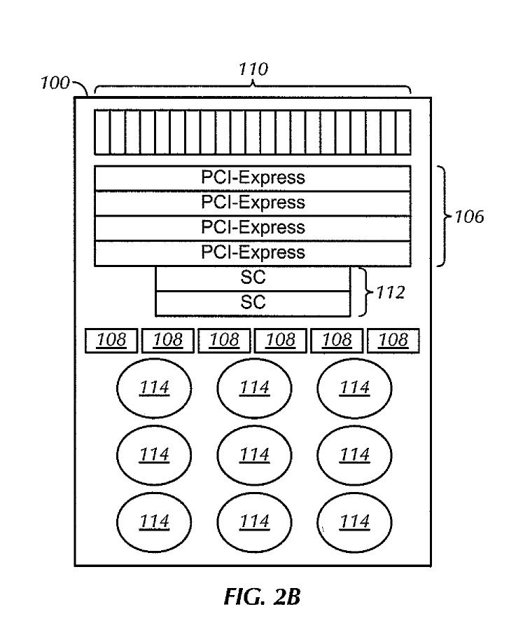

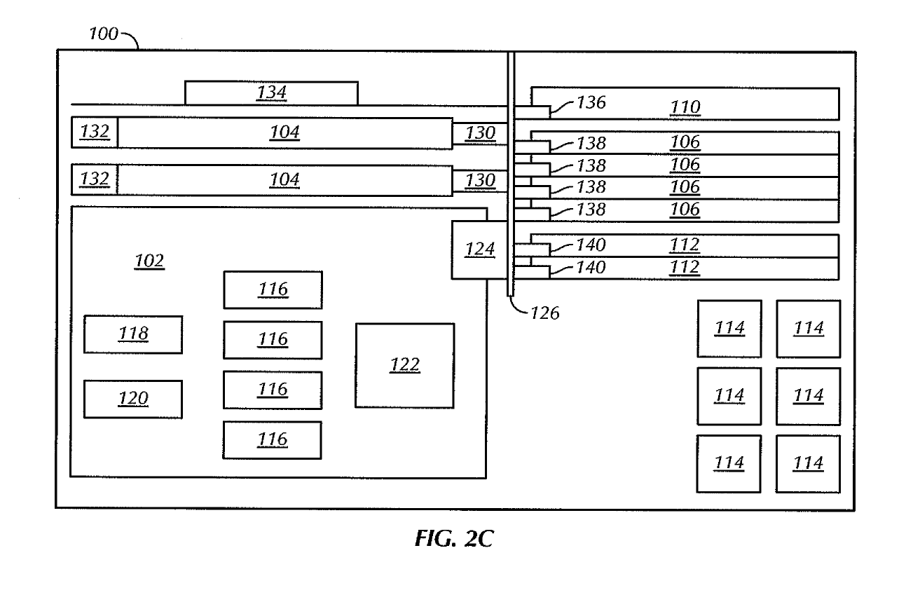

FIG. 2A shows a front view of a chassis 100 of a blade server in accordance with an embodiment of the present invention. The chassis 100 has a plurality of bays for receiving and at least partially housing a plurality of CPU modules 102. Further, a plurality of power supply units 104 may be accessed from the front side of the chassis 100.

Those skilled in the art will note that although FIG. 2A shows a particular number of bays for the plurality of CPU modules 102 and power supply units, any number of bays and power supply units may be used.

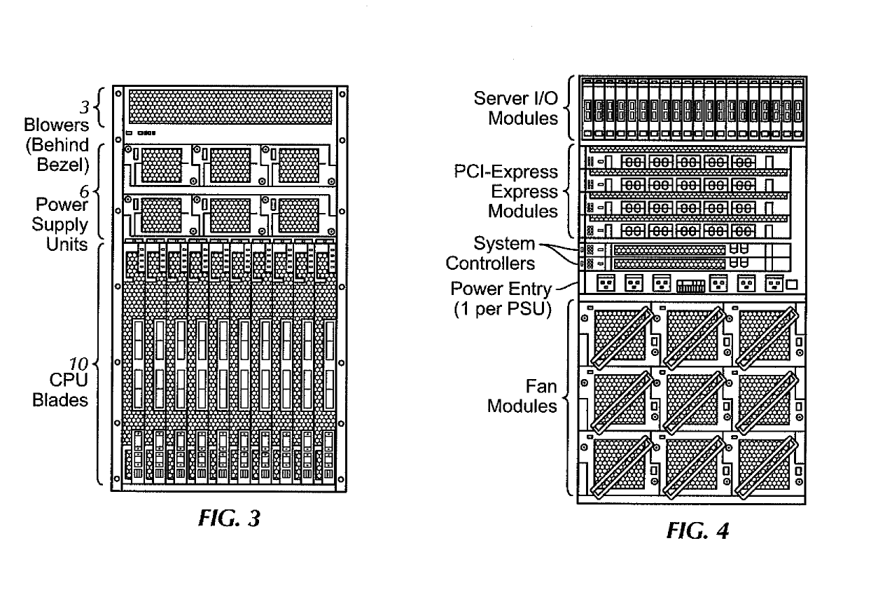

Moreover, FIG. 3 depicts an example of a front side view of a blade server in accordance with an embodiment of the present invention.

FIG. 2B shows a rear view of the chassis 100 in accordance with an embodiment of the present invention. The chassis 100 has a plurality of bays for receiving and at least partially housing a plurality of Network Express modules 106. Further, the chassis 100 has one or more electrical recesses for plugging AC power cords 108 into the chassis 100. In one or more embodiments of the present invention, the number of inputs for AC cords 108 may depend on the number of power supply units 104.

Further, the chassis 100 has a plurality of bays for receiving and at least partially housing PCI-E Express modules 110. Further, the chassis 100 has a plurality of bays for receiving and at least partially housing one or more system controller modules 112. Moreover, a plurality of fans 114 may be positioned along a rear side of the chassis 100, the plurality of fans being arranged to direct heated air from the front side of the chassis 100 to and through the rear side of the chassis 100.

In one or more embodiments of the present invention, one or more of the various components described above with reference to FIGS. 2A and 2B may be hot-swappable.

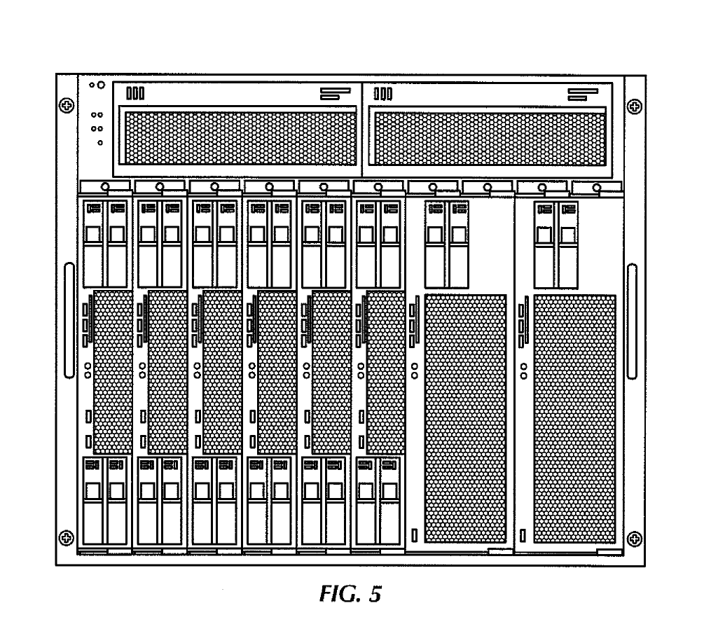

Moreover, FIG. 4 depicts an example of a rear side view of a blade server in accordance with an embodiment of the present invention.

FIG. 2C shows a cross-sectional side view of the chassis 100 in accordance with an embodiment of the present invention. The CPU module 102 (other CPU modules not shown) has a plurality of CPUs 116 that may have one or more processing cores. Further, as shown in FIG. 2C, the CPU module 102 has storage devices 118, 120 and memory 122.

The CPU module 102 is connected via connector 124 to a printed circuit board (PCB), which may be a midplane board 126. The midplane board 126 is further connected by connectors 136, 138, 140 to PCI-E Express modules 110, Network Express modules 106, and system controller modules 112, respectively. The midplane board 126 implements the PCI-Express connectivity between the PCI-E Express modules 110 and the CPU module 102, and thereby may, for example, logically assign PCI-E Express modules 110 to a particular group of CPU modules.

With respect to the PCI-E Express modules 106, in one or more embodiments of the present invention, two PCI-E Express modules 106 may be assigned to one CPU module.

The system controller modules 112 may be responsible for chassis management functions and may also provide a management ethernet switch fabric that connects the system controller modules 112 to the CPU modules (e.g., CPU module 102) and the Network Express modules 106. Further, in one or more embodiments of the present invention, one or more of the system controller modules 112 may provide an external connectivity to a management network at an installation site.

Further, as shown in FIG. 2C, the midplane board 126 is connected to each power supply unit 104 by bus 130. Moreover, a fan 132 is provided to cool each power supply unit 104, where air flow is at least partially directed by a blower 134.

The midplane board 126, at least partially as described above, (i) provides mechanical connection points for the CPU modules 102, (ii) provides standby power from the power supply units 104, (iii) provides PCI-Express interconnect between the various connectors 124, 136, 138, 140, and (iv) connects, for example, the CPU modules 102, the system controller modules 112, and the Network Express modules 106 to a management network for the chassis 100.

In regard to the Network Express modules 106, those skilled in the art will note that the Network Express modules 106 allow for configurable I/O for the CPU modules 102 in place in the chassis 100. In other words, the PCI-E Express modules 106 provide a way to configure I/O for all CPU modules 102 in the chassis 100 using, for example, a single physical module. By combining the I/O of all CPU modules 102 in one Network Express module 106, it may be become possible to support I/O aggregation functions on a given Network Express module 106.

As is discernible from the description above with reference to FIGS. 2A, 2B, and 2C, the CPU modules 102 and/or power supply units 104 may be accessible through a front side of the chassis 100, and the PCI-Express modules 110, the system controller modules 112, the Network Express modules 106, and fans 114 may be accessible through a rear side of the chassis 100.

Further, those skilled in the art will note that in one or more embodiments of the present invention, access of modules/components in the chassis 100 may be achieved without the use of one or more special tools.

Further, a blade server, in accordance with any of the embodiments described above with reference to FIGS. 2A, 2B, 2C, 3, and 4, may be implemented with exhaustive fault detection mechanisms for monitoring for and/or detecting fault events of the various components and modules described above.

Advantages of the present invention may include one or more of the following. In one or more embodiments of the present invention, a blade server relies on PCI-Express I/O, thereby possibly resulting in increased space efficiency and/or operational performance.

In one or more embodiments of the present invention, a blade server may have support for a plurality of single core or multi-core CPUs.

In one or more embodiments of the present invention, PCI-Express signals from all blades in a blade server connect to a single I/O expansion module.

In one or more embodiments of the present invention, a blade server may provide for complete separation between CPU and I/O modules. Thus, blade servicing may be performed without affecting cabling or I/O configuration.

In one or more embodiments of the present invention, a chassis management infrastructure for a blade server may be based upon a pair of redundant hot-swappable system controller modules that operate in conjunction with a Service Processor on each blade to form a complete chassis management system.

In one or more embodiments of the present invention, a chassis of a blade server may integrate AC power supplies and cooling fans, so that blades do not contain either, making them more reliable.

In one or more embodiments of the present invention, a blade server is modular.

In one or more embodiments of the present invention, power supply units and fans in a chassis of a blade server may be designed for ease-of-service, hot-swappability, and/or redundancy.

In one or more embodiments of the present invention, a blade server may support any type of I/O expansion with industry standard PCI-E Express modules.

In one or more embodiments of the present invention, a blade server may provide support for flexible I/O configurations based on, for example, industry-standard I/O modules.

In one or more embodiments of the present invention, a blade server has a dedicated air flow zone for blades that are cooled by redundant rear chassis fans, where the air flow zone may be separated from the air flow zone for the power supplies and I/O of the blade server.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

A detailed example of a modular blade server in accordance with the present invention is presented below in the form of a product specification. This specification describes the functionality, major components and subsystems, external interfaces, and operation of a modular blade server is referred to as a Sun Blade Modular system.

A second detailed example of a modular blade server in accordance with the present invention is further presented below in the form of a product specification. This specification describes the functionality, major components and subsystems, external interfaces, and operation of a second exemplary modular blade server is referred to as the Sun Blade 8000 Modular System, available from Sun Microsystems, Inc.

A Sun Blade Modular system is a high-performance blade server that is designed to replace traditional rack-mount servers for both enterprise and technical markets. The Sun Blade Modular system supports 500 W power and cooling per blade sufficient for the highest performance multi-core CPU chips. The Sun Blade Modular system blade form factor supports large CPU, memory, and I/O configurations. The Sun Blade Modular system supports two PCI Express Modules per blade. The Sun Blade Modular system has two redundant Network Express Modules that provide pass-through and/or shared or virtualized network interfaces. Each blade includes an integrated service processor that supports remote management including KVMS for industry-standard architecture CPU blades. The Sun Blade Modular system has hot swappable redundant power and cooling. Blades, Power Supplies, PCI Express Modules, Network Express Modules and the Fan Modules all are hot-swappable customer replaceable units (CRUs). The Sun Blade Modular system supports high performance CPUs with large memory an up to 128 Gbps of input/output per blade.

A chassis summary of the Sun Blade Modular system is: Size (H×W×D)=10 U: 17.4″×17.4″×28″ (442×442×711 mm); Front CRUs=10 Single-wide Blades and 2 Power Supplies; Rear CRUs=20 PCI Express Modules, 2 Network Express Modules, 6 Fan Modules, and Chassis Management Module; Power=2×6000 W, 200-240V Input Voltage; Cooling=6 Fan Modules.

The Sun Blade Modular system AMD Opteron™ (AMD Opteron™ is a trademark of AMD Corporation) Blade Summary is set forth below in Table 1.

TABLE 1
Blade Summary

| | | |
|---|---|---|
| CPU | 2 Socket AMD Opteron ™ | 4 Socket AMD Opteron ™ |
| Blade | | |
| CPU | 2 Sockets REV-F | 4 Sockets REV-F |
| | 120 W max power | 95 W max Power |
| | Dual Core | Dual Core |
| Memory | DDR2 PC2-3200R ECC | DDR2 PC2-3200R ECC |
| | 16 DIMM Sockets | 32 DIMM Sockets |
| | 1, 2, or 4 GB DIMMs | 1, 2, or 4 GB DIMMs |
| I/O | 2 PCI Express Modules | 2 PCI Express Modules |
| Expansion | 2 Network Express Modules | 2 Network Express Modules |
| | Dual Gigabit Ethernet | Dual Gigabit Ethernet |
| | Disks 4 × 2.5″ SAS/SATA | None |

The Sun Blade Modular system is designed for ease of service. All front and rear modules are book-packaged CRUs that are designed with tool-less extraction and indefinite service time. In addition, the Sun Blade Modular system offers the following RAS features: hot-swappable grid-redundant power supplies; hot-swappable redundant fan modules; hot-swappable CPU blades, PCI Express and Network Express Modules; hot-swappable disk drives; ECC protected memory and cache; automatic server restart; network based booting capability; Network based OS and BIOS upgrades; System error logging; Environmental monitoring; Trusted Platform Module (TPM); Vital Product Data (VPD); Standard System Indicators; Rapid Response Lighting; and Tool-less chassis design.

The Sun Blade Modular system is a rackmount blade server that supports 10 blades in a 10 U high chassis. The Sun Blade Modular system uses a midplane design with various hot-swappable CRUs installed from the front and the rear of the chassis. The following CRUs are installed from the front: 10 Blades; and 2 power supply units. The following CRUs are installed from the rear: 20 PCI Express Modules (two per blade); 2 Network Express Modules; 6 Fan Modules; and Chassis Management Module.

These CRUs are described in more detail below. All cabling is in the rear of the chassis with the exception of the I/O diagnostic connector on front of the blade that supports a diagnostic cable for blade configuration and diagnostic procedures.

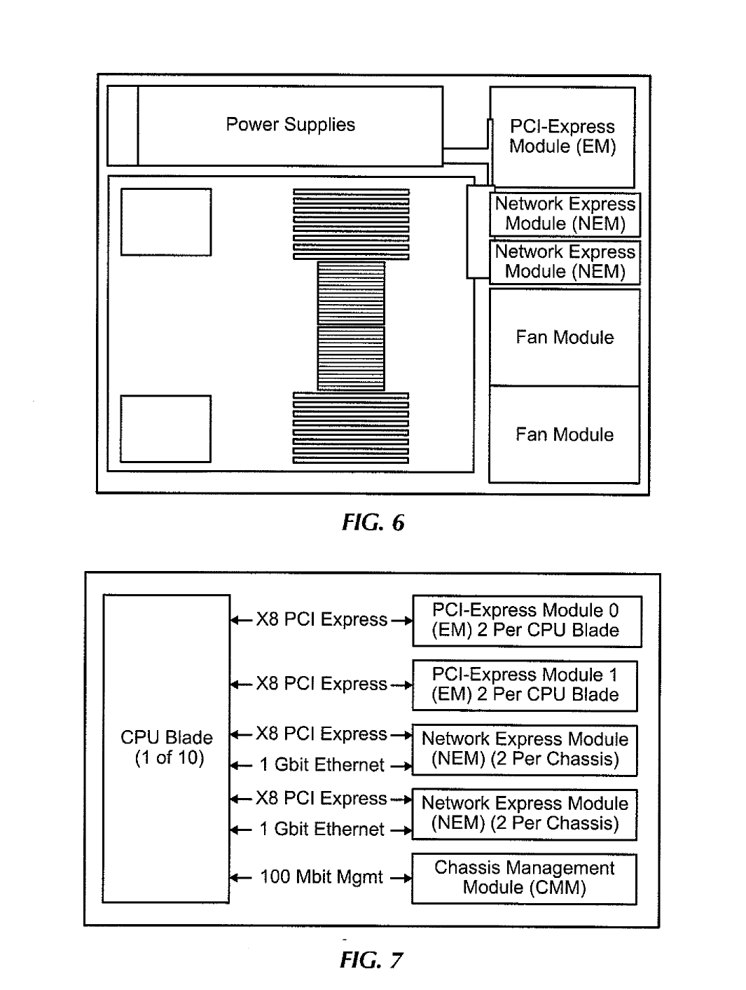

The Sun Blade Modular system chassis front view is shown in FIG. 5. The Sun Blade Modular system Chassis side view is shown in FIG. 6. As can be seen, the chassis of the Sun Blade Modular system has two airflow zones. The blades are cooled with six redundant fan modules that provide a minimum of 60 CFM of airflow per blade. The power supplies have built-in fans that cool the power supplies and also provide cooling for the PCI-E Express modules, the Network Express modules, and the chassis management module.

The Sun Blade Modular system includes upper chassis cooling of fans within the PSU that cool the PSU, the PCI-Express modules, and the Network Express modules, with air flow direction from front to rear. The air flow required from each PSU is 100 CFM. The fans in each power supply are capable of delivering 100 CFM against chassis back pressure of 0.3 inches of H₂O in addition to the power supply back pressure. In the case of a failed PSU, the fans in the failed PSU continue to operate as long as there is 12V power on the midplane, thereby maintaining ˜100 CFM of air flow.

The Sun Blade Modular system is designed to support both SPARC and industry standard ×64 architecture blades, as well as future storage and other special purpose blades. As a result, the chassis system architecture was designed to be independent of any particular CPU architecture.

Each Sun Blade Modular system blade supports two PCI-Express modules and two Network Express modules for I/O Expansion. The PCI-E Express modules provide direct I/O expansion for each blade, whereas the Network express modules provide shared and/or virtualized I/O for all the blades in the chassis. In addition, the service processor on each blade connects to the chassis management module (CMM) that aggregates the individual out-of-band Ethernet management ports into one external out-of-band Ethernet management port for the entire chassis. The arrangement of these modules relative to each CPU blade is shown in FIG. 7.

The Sun Blade Modular system supports two industry standard PCI-E Express modules (EMs) per CPU blade, each with eight PCI-Express lanes, providing flexibility to address different 10 requirements. The Sun Blade Modular system supports two Network Express modules (NEMs) per chassis. Each NEM provides one pass through Gigabit Ethernet port per blade as well as one 8×PCI-Express port per blade to provide shared or virtualized network interfaces such as 10 Gigabit Ethernet. The sharing of high-speed network ports provides an order of magnitude reduction in network wires and switch costs and enables virtualization of the network interface across multiple blades.

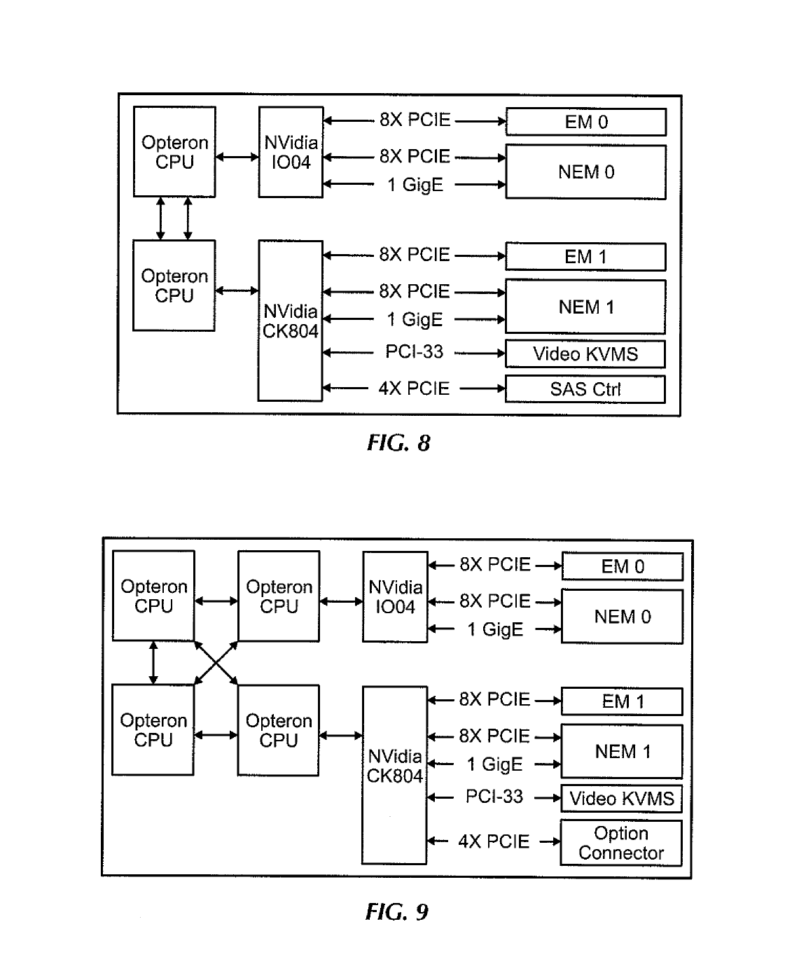

The Sun Blade Modular system Dual AMD Opteron™ Blade includes: Two AMD Opteron™ REV-F CPUs, 16 DDR DIMMs (0.5, 1, 2, 4 Gbyte each), CK804/IO04 PCI-Express Bridge chips, 32 PCI-Express lanes I/O, 2 GigE ports, 4 hot-swap 2.5 SAS disks, Compact Flash Boot Device, KVMS service processor, configured as shown in FIG. 8.

The Sun Blade Modular system Quad AMD Opteron™ Blade includes: Four AMD Opteron™ REV-F CPUs, 32 DDR DIMMs (0.5, 1, 2, or 4 Gbyte each), 2 GigE ports, Compact Flash Boot Device, KVMS service processor, configured as shown in FIG. 9.

The Sun Blade Modular system management involves a distributed management system with a blade service processor on each blade and a chassis service processor on the chassis management module. This design has the advantage that each blade service processor can directly interact with a network based management system without having to go through a centralized chassis management agent. The midplane provides two mechanisms to support this distributed management system: (1) A switched system management network that connects all service processors within the chassis and presents a single external 1000-Base-T Ethernet management port; and (2) A shared system management bus allows each blade to directly access chassis status, including chassis configuration, power supply and fan status. The combination of these two mechanisms enables distributed system management without the need for a central management agent with the associated single points of failure, redundancy and failover issues.

The Sun Blade Modular system midplane includes: All modules, except the power supplies and the fan modules, connect directly to the midplane. The power supplies connect to the midplane through a bus bar and to the AC inputs with a cable harness. The six fan modules plug individually into one of three fan boards that connect to the midplane. The midplane provides the following functions: (1) 12 VDC main power and 3.3 VDC aux power distribution to all modules; (2) PCI-Express interconnect between the blades and the PCI Express Modules; (3) PCI-Express interconnect between the blades and the Network Express Modules; (4) Network I/O connectivity between the blades and the Network Express Modules; (5) Ethernet Management connections between the blades and the CMM; (6) System Management Bus for all modules in the chassis; (7) System Indicator Bus for all modules in the chassis; (8) Dual ADM1026 fan controllers; (9) PCA9698 for chassis status signal aggregation; (10) PCA9501 to provide the Midplane FRUID.

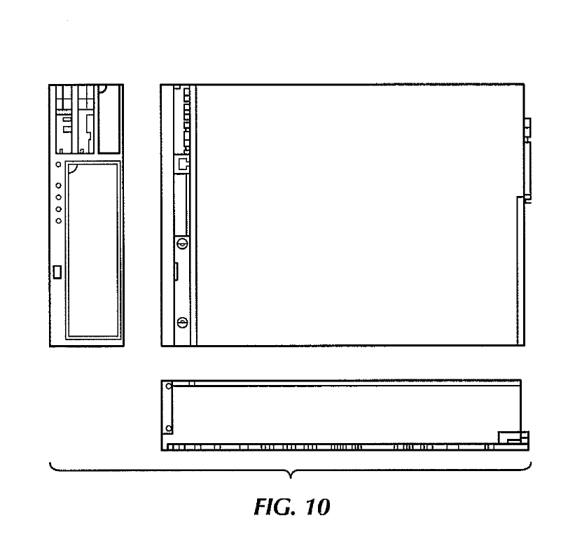

The Sun Blade Modular system blade physical specification is: Blade size=The single-width blade is 326.6 mm (12.85) high (guide to guide), 498.1 mm (19.62) deep (front face to rear of housing) and 43.8 mm wide (blade to blade) as shown in FIG. 10. Blade PCB size=The maximum blade PCB size is 12.5×19.5 which fits two boards per 21×27 PCB panel or four boards per 48×54 sheet.

The Sun Blade 8000 Modular system is a blade server optimized for high performance applications which place high demands on CPU performance, memory capacity, and I/O bandwidth. In order to accommodate such applications, the Sun Blade 8000 Modular system CPU blade architecture provides four (4) CPU sockets, sixteen (16) DDR1-400 DIMM sockets, and up to 48 lanes of PCI-Express I/O. The CPU sockets will support both single-core and dual-core AMD Opteron™ CPUs, and supported memory DIMMs will include 1 GB and 2 GB at initial revenue release, with support for 4 GB DIMMs phased in soon thereafter.

The Sun Blade 8000 Modular system chassis accommodates very high I/O bandwidth via a number of plug-in modules on the rear of the chassis. The Sun Blade 8000 Modular system design provides a power and cooling infrastructure to support current and future CPU and memory configurations. The key characteristics of Andromeda are: support for up to four single-core or dual-core AMD Opteron™ CPUs. Thus, up to 8 CPU cores per blade are provided. The cooling and power distribution systems of the Sun Blade 8000 Modular system blades are designed to handle future 140 W CPU chips and CPUs with more than two cores.

There is a complete physical separation between CPU and I/O modules. Sun Blade 8000 Modular system uses industry-standard PCI-Express Express modules (EM) for “blade-at-a-time” I/O configuration, and a Network Express module (NEM) for “bulk” I/O configuration and I/O aggregation. Blade servicing can be performed without affecting cabling or I/O configuration. EM and NEM modules are also hot-swappable independently of the blades.

The system management infrastructure is based on industry-standards. Each Sun Blade 8000 Modular system blade contains its own directly addressable service processor supporting IPMI, SNMP, CLI, and HTTP management methods. The chassis management infrastructure is based upon a pair of redundant hot-swappable system controller (SC) modules that work in conjunction with a service processor (SP) on each blade to form a complete chassis management system.

The highly reliable chassis is designed for a long life-cycle. The Sun Blade 8000 Modular system chassis integrates AC power supplies and cooling fans, so that the blades do not contain either. This makes the blades more reliable. Power supplies and fans in the chassis are designed for ease-of-service, hot-swappability, and redundancy. All other shared components, such as system controllers or NEMs are redundant and hotswappable. Support for flexible I/O configuration options is based on industry-standard PCI-E Express modules. Thus, the Sun Blade 8000 Modular system design supports any adapters for networking, storage, clustering and other I/O functions. The Sun Blade 8000 Modular system design allows flexible blade configuration options.

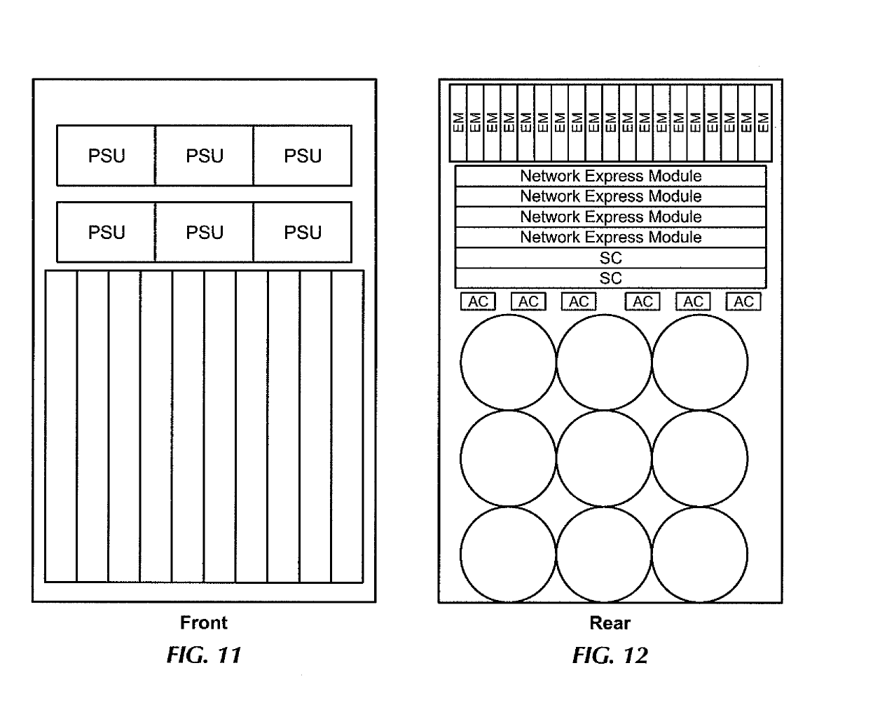

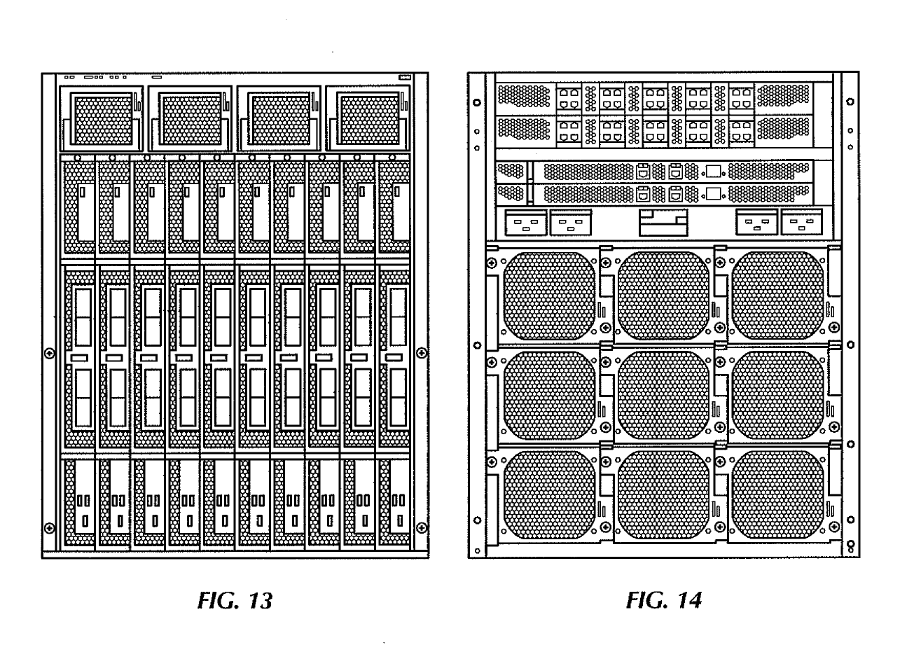

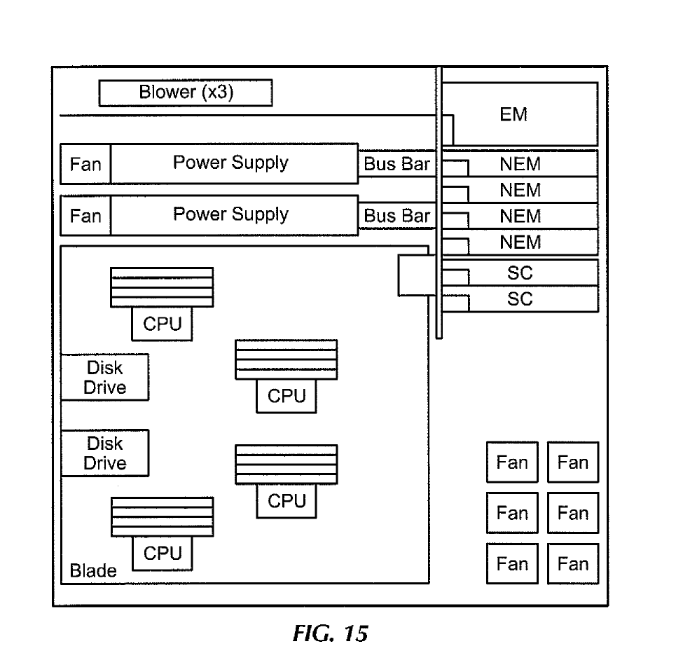

The Sun Blade 8000 Modular system chassis is shown in FIGS. 11-14. The blades are accessible from the front of the chassis, along with the six power supplies. The rear of the chassis has 20 PCI-E Express modules or EMs (which until recently were called server I/O modules or SIOMs), 2 System Controller Modules, and 4 Network Expansion Modules (NEM), as well as 9 fan modules. All these components are hot-swappable. The Sun Blade 8000 Modular system Chassis Configuration side-view is shown in FIG. 15. Although not drawn to scale, this figure illustrates the relative positions of the various FRUs that comprise the Sun Blade 8000 Modular system.

The midplane includes: All modules, front and rear, with the exception of the AC input and the system fans, which connect directly to the midplane. The power supplies connect to the midplane through a bus bar. AC distribution is via a cable harness from the AC inlets into floating connectors for each power supply. The fans modules (each module with two fans) plug individually to a set of three (3) fan boards, where fan speed control and other chassis-level functions are implemented. The blowers, which provide the air circuit that cools the Express Modules, each connect to the chassis via blind-mate

The main functions of the midplane are: providing mechanical connection points for all blades; providing 48V and 12V standby power from the power supplies to each FRU; providing PCI-Express interconnect between the PCI-Express root complexes on each blade to the Network Express modules and EMs. The midplane provides six (6) ×8 PCI-Express links; one (1) from each blade to each of the four (4) NEMs, and one (1) from each blade to each of two (2) EMs; and connecting the blades, SCs, and NEMs to the chassis management network.

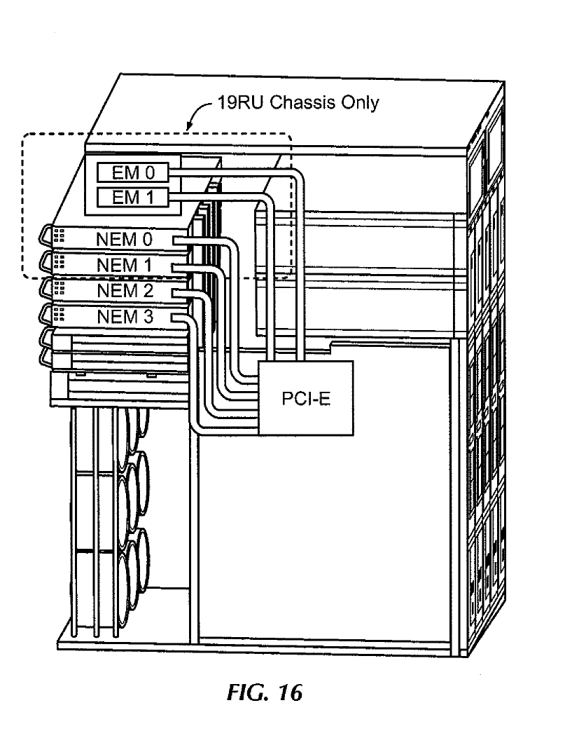

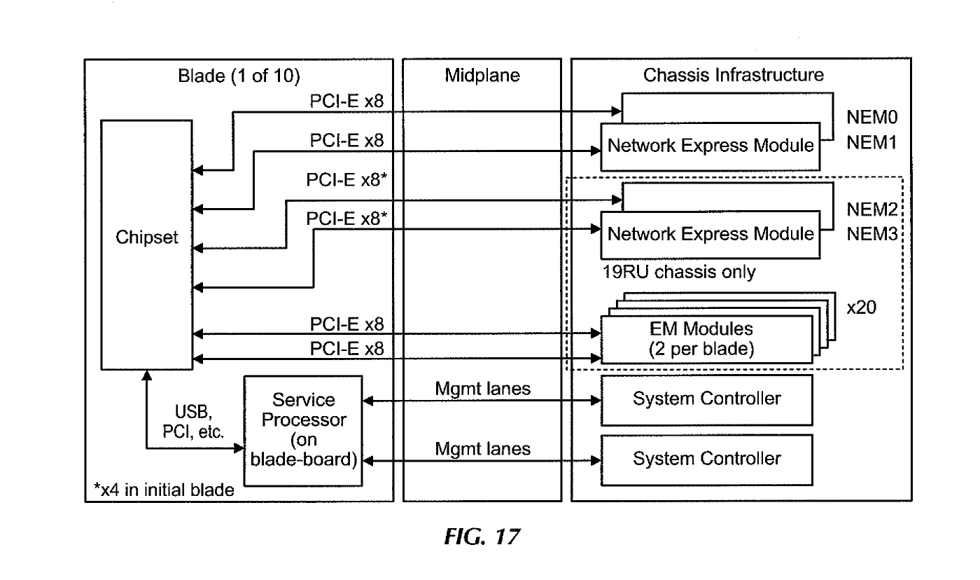

FIG. 16 shows various exemplary embodiments of the Sun Blade 8000 Modular system blade server interconnect of internal components with each other. Shown in FIG. 17 is a schematic configuration of the exemplary blade server I/O distribution.

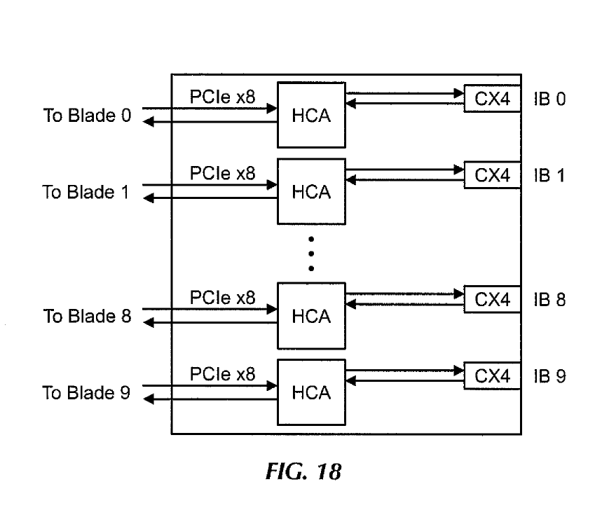

The Sun Blade 8000 Modular system also includes a plurality of network Network Express modules that: are single-purpose I/O module (Ethernet, FC, IB); aggregate one ×8 PCI-Express link from each blade; enable I/O pass-through and/or switching; are hot-pluggable, modular, and customer replaceable; and have four NEM slots per 19 RU chassis (Two per 14 RU chassis). An example of how NEMs are configured is shown in FIG. 18.

The Sun Blade 8000 Modular system chassis is designed for ease-of-service by either the customer for user-upgradeable components or by authorized service personnel. The following are directly hot serviceable by users, from either the front or rear, on a live system. With the exception of the power supplies, all FRUs may be serviced without the use of tools: server blades (front); power supply units (front); EM I/O modules (rear); system controller modules (rear); Network Express modules (rear); and system fans (rear). In addition, authorized service personnel can replace the “I/O Carrier” which includes the midplane, AC inlets and main cable harness. This action requires the system to be powered down and requires the use of tools. In addition to the I/O Carrier, a small number of components, such as indicator modules, may be attached to the chassis and/or cabled to the midplane. These remaining components are also intended to be serviced by authorized service personnel only.

The Sun Blade 8000 Modular system chassis provides two parallel management fabrics: 100BaseT Ethernet and I2C, which connect the SC modules to the managed FRUs, i.e., the blades and NMs. Additionally, the Ethernet and I2C management fabrics connect the two SC modules to each other. The management network internal to the Sun Blade 8000 Modular system chassis joins the local management processor on each FRU. Specifically, this provides connectivity among the Blade Service Processors, NEM management processors, and the SC processors. The management network is formed via a set of Ethernet switch chips on the SC modules. Thus, there are two parallel and separate physical management networks formed by the switch fabric on each SC module. The management subsystems on the blades, NEMs, and SC modules each provide two separate network interfaces, allowing them to each connect to both management networks. The embedded software environment which runs on each of these types of FRUs implements a technology called NIC bonding, by which the embedded management software sees its two NICs as though they were one, thereby facilitating failover from one management network to the other.

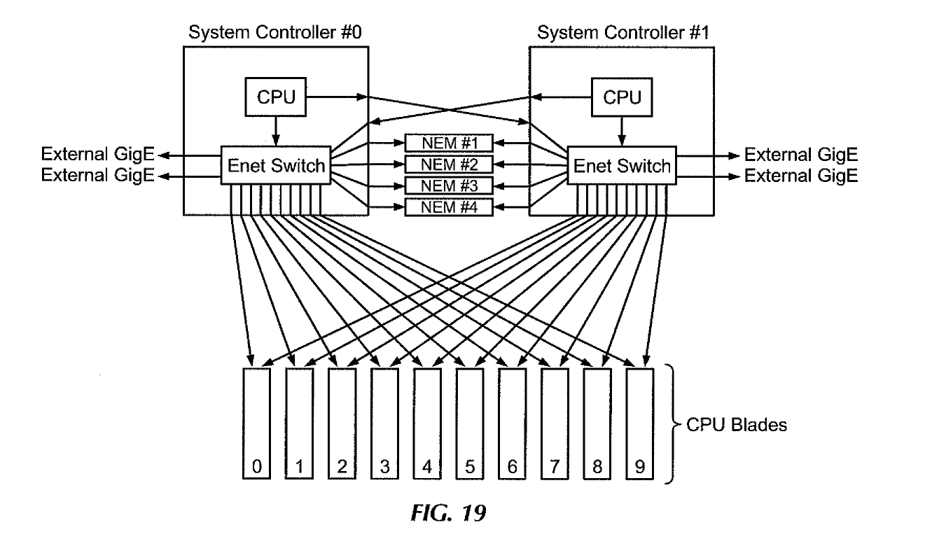

The topology of the management Ethernet network is shown in FIG. 19. Note that each SC module's processor originates two Ethernet links, one of which connects to its local Ethernet switch and the other of which connects to the other SC module's Ethernet switch. For illustrative purposes, the Ethernet switch is shown as a single component. In fact, the switch is built out of two smaller interconnected switches. The two links which connect to each blade and each NEM are connected directly to the two NIC interfaces provided by the management processor on each of these FRUs. Thus, every management processor in the system has two paths to every other management processor as well as two paths out of the chassis via the external Gigabit links that leave the rear of each SC module.

An exemplary Sun Blade 8000 Modular system server blade includes the following features: Four AMD Opteron™ CPUs, single or dual core; 16 PC3200R registered ECC DIMMs, four (4) per CPU (The DIMMs are configured in pairs in order to maximize performance and to take advantage of the AMD Opteron™ CPU's chip-kill feature (Individual CPUs may be configured with or without attached memory of 512 MB, 1 GB, and 2 GB DIMMs); Two hot-swappable SAS or SATA drives, accessible from the front of the blade; nVidia CK8-04 bridge providing 20 lanes of PCI-Express and Southbridge functionality; nVidia IO-4 bridge (a version of the CK8-04 without the Southbridge functionality) providing another 20 lanes of PCI-Express; a Service Processor providing remote KVMS, IPMI BMC functionality and software interfaces to the system controller modules located in the chassis rear (The SP and SCs work together to form complete blade and chassis management functionality); and Front-panel I/O of: VGA, 2×USB, and Serial for emergency management.

The blade architecture provides legacy 32-bit/33 MHz PCI connectivity as needed for the disk and video subsystems, while the main I/O subsystem for application use is provided exclusively by 40 lanes of PCI-Express which connect each blade's CPU subsystem to the NEM and Express Modules plugged into the chassis rear. The backplane provides six (6) ×8 PCI-E links and two management 10/100 Ethernet. The PCI-E Express modules are allocated per blade as follows: One (1) ×8 link to each of the four (4) NEMs; and One (1) ×8 link to each of two (2) EMs. The six ×8 PCI-E links provide flexible and upgradeable I/O. These links connect through the midplane to the internal EM and to the Network Express modules (NEM) and through the NEM to external I/O expansion cabinets or to shared I/O functions. The combined I/O bandwidth available to the blade is 15 GB/sec in each direction.

The blade is approximately 19.5″×18.5″×1.75″ (height×depth×width). Each blade features on its front panel the standard system indicators (Power, Attention, Locate, OK-to-Remove,) reset and power pushbuttons, and a connector for analog Video, dual USB, and serial port. Each blade contains its own power distribution starting from the 48V provided by the power supplies. The blade also provides 12V and standby power to its two associated EM modules. I/O Connectivity is provided through the combination of the Network Express modules (NEMs) and PCI-E Express Express modules (EMs).

The NEMs provide configurable I/O on a “10-blades-at-a-time” basis. The NEMs are a very space efficient mechanism for providing configurable I/O and are the key mechanism for providing the I/O density Apportioning separate physical PCI slots to individual rack-mount servers is an inefficient use of rear-panel real estate. The Sun Blade 8000 Modular system, with its NEMs, provides a higher CPU-memory-I/O density when compared to a similar configuration of 4-way rackmount systems. NEMs provide a way to configure I/O for all blades in a chassis using a single physical module. By combining the I/O functions of all blades in one module, it is also possible to support I/O aggregation functions on a given NEM.

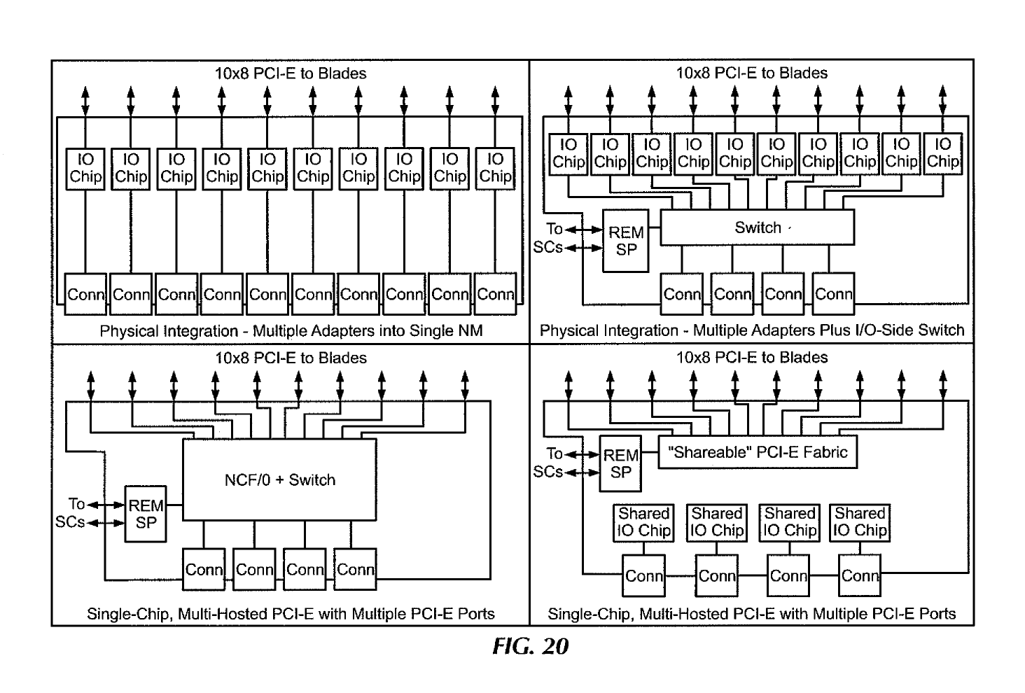

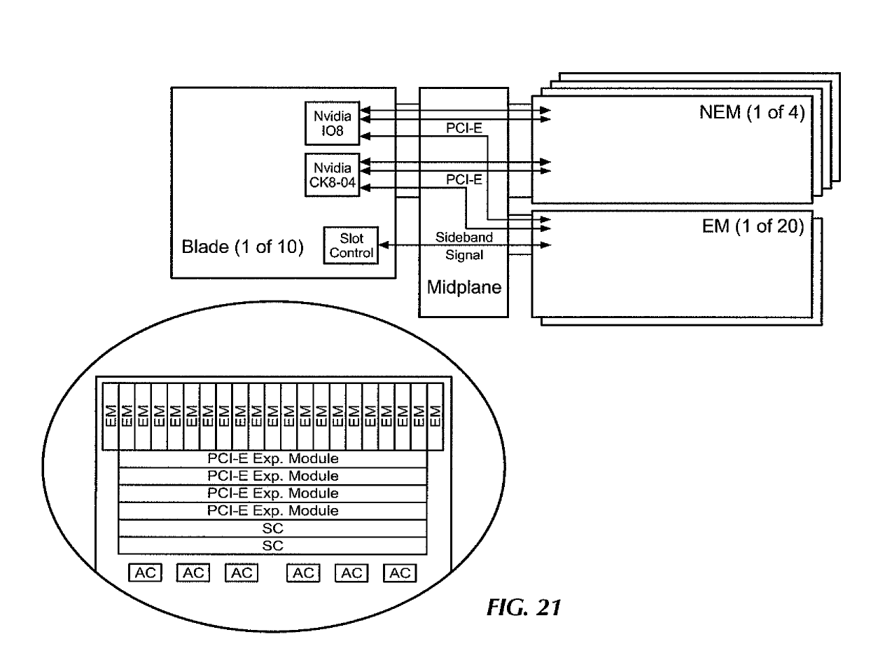

FIG. 20 shows some exemplary embodiments of NEM I/O architectures. In one or more embodiments, individual I/O functions are provided for each blade on its dedicated PCI-E interface, with the resulting S/O interfaces being individually exposed. The NEM may be designed as a Gigabit Ethernet NEM providing a dual GbE NIC to each blade and exporting all resulting 20 GbE links out the rear via RJ45 connections. An example of a similar NEM uses 10 Fibre Channel HBA chips with 10 (or 20) FC interfaces in the rear I/O panel.

One or more embodiments involve the addition of an aggregation function to the I/O interface. In such embodiments, each blade still owns a dedicated I/O chip, such as an Ethernet NIC, but instead of bringing each blade's I/O interface out to the rear panel, the NEM provides an aggregation function such as an embedded Ethernet switch. By providing high bandwidth links at the rear panel, such as 10 GbE, the NEM implements an aggregation function, thereby reducing the cabling needs of the chassis. The aggregation is specific to each I/O technology, such as the aforementioned GbE switch with 10 GbE uplinks, or an FC switch with 4 Gbps uplinks. The number and type of uplinks is also a function of the technology and the desired capabilities. The NEM architecture includes the possibility of a local intelligent “switch processor” (resident on the internal Ethernet management network) that manages the I/O switch depending on needs.

In one or more embodiments each blade is directly connected to two EMs, and to four NEMs, as shown in FIG. 21. The EMs offer independent, dedicated I/O functions on a per blade basis. For example, one blade can be configured with redundant Fibre Channel EMs, while another blade may have a single Fibre Channel EM and a single InfiniBand EM.

The Sun Blade 8000 Modular system provides a number of interfaces by which it is managed. Each individual blade provides IPMI, HTTP, CLI (SSH), SNMP, and file transfer (Secure Copy, FTP, TFTP) interfaces that are directly accessible from the Ethernet management port on the SC. Each blade is assigned an IP address (either manually, or via DHCP) that is used for this purpose. The management functions provided by the blade are related to individual blade management and do not provide significant chassis management functions. The SC, on the other hand, is the primary point of management of all shared (chassis) components and functions. The SC provides a similar set of management interfaces (though an IPMI interface is not yet being considered), but the elements being managed are different. An IP address is assigned (again either manually configured or acquired via DHCP) to the Master SC. This IP address “floats” with the Master SC. That is, it is always associated with the SC that is currently functioning as the Master SC. The SC provides only limited blade management functions, but does support HTTP and CLI “pass-through” interfaces that provide access to the blade.

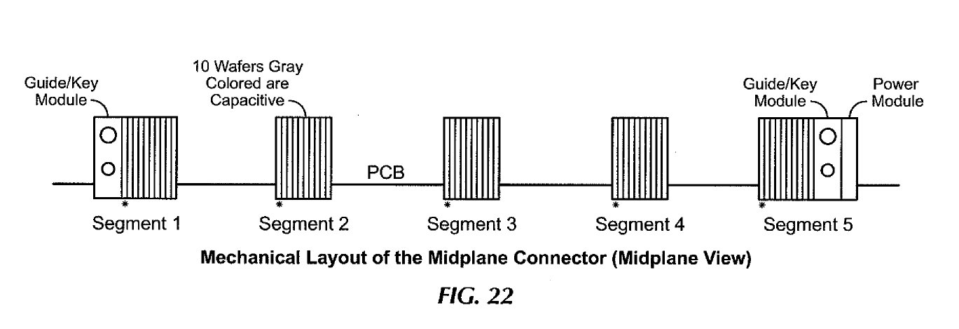

The midplane connector of the Network Express module consists of five GbX connector segments. Each segment contains ten wafers. Four of the wafers (wafer #: 2, 3, 8, 9) are capacitive ones. The capacitive wafers implement the required AC coupling for the PCI-E links. FIG. 22 shows the mechanical layout (midplane view) of the midplane connector.

The pin assignments of the midplane connector are shown below in Table 1. The following three signals are connected to short pins: PRSNT_N-PEM presence detect output for the SCs; INSERTED_N-PEM inserted input (it is connected to the logic ground in the midplane); and SOFTSTART_N-Enable signal of the soft start controller IC in the PEM (it is connected to the 48V_RETURN in the midplane).

TABLE 1
Pin Assignments of the midplane connector.

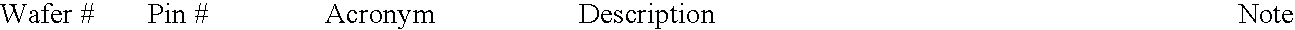

CONNECTOR SEGMENT 1

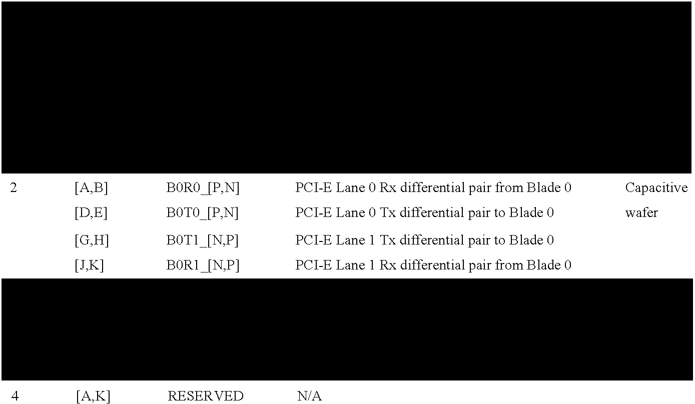

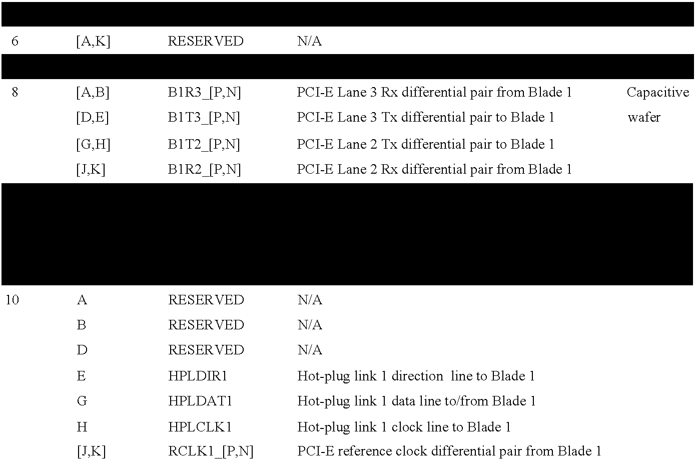

CONNECTOR SEGMENT 2

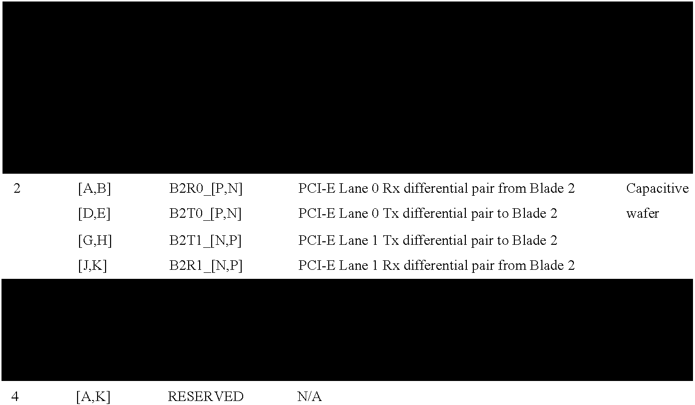

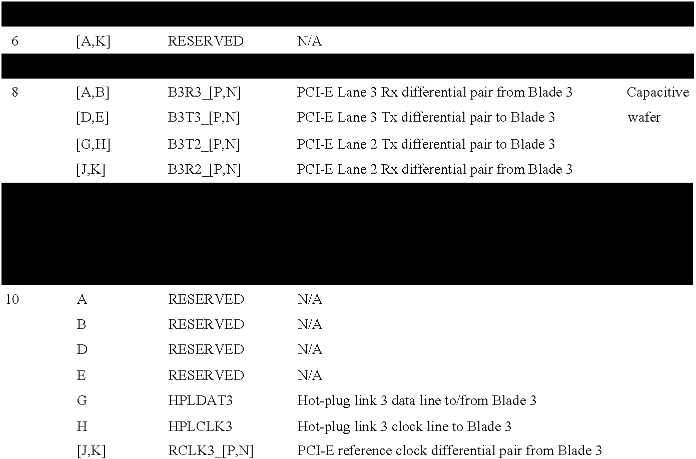

CONNECTOR SEGMENT 3

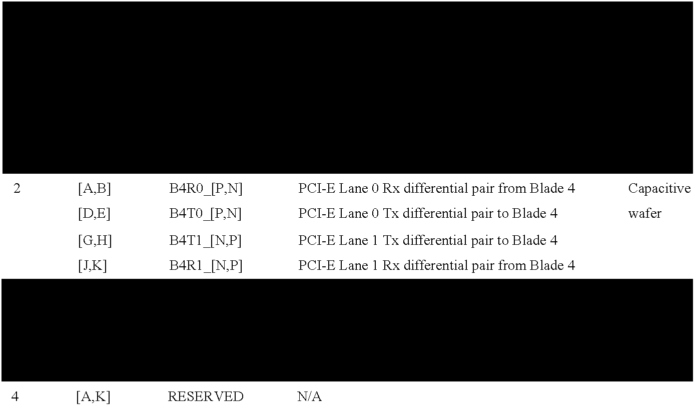

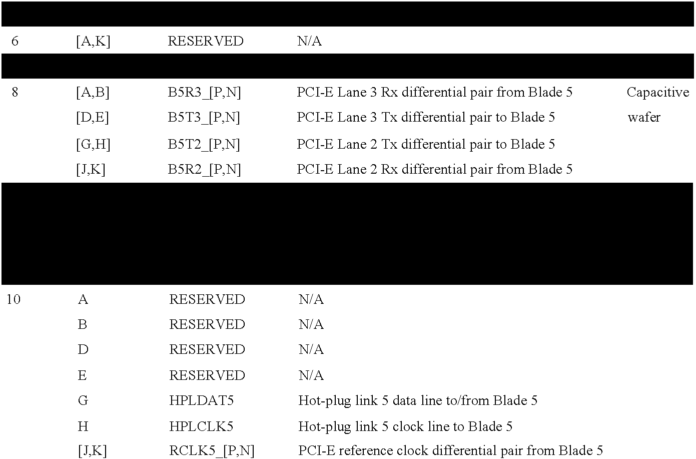

CONNECTOR SEGMENT 4

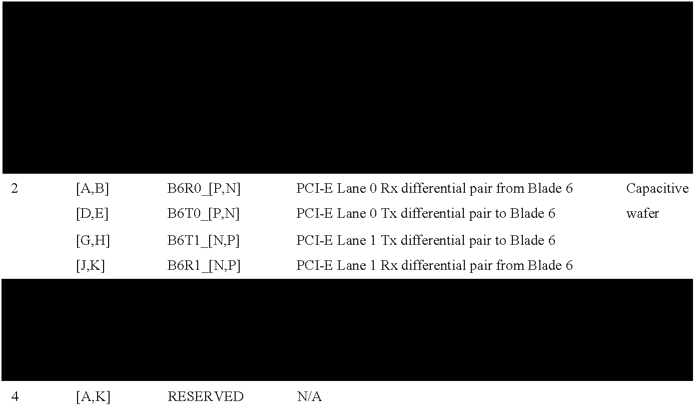

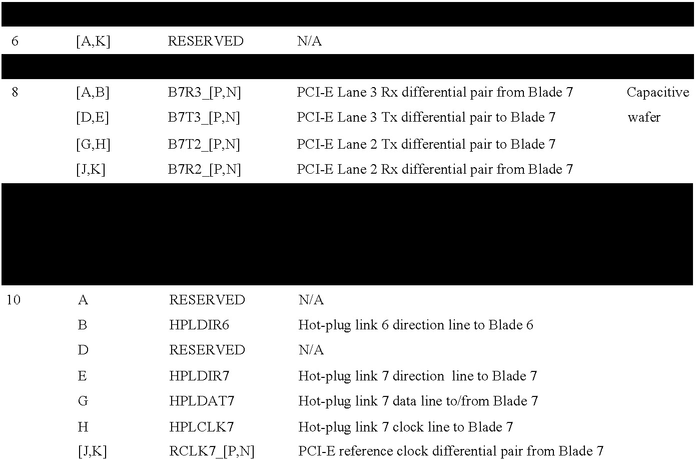

CONNECTOR SEGMENT 5

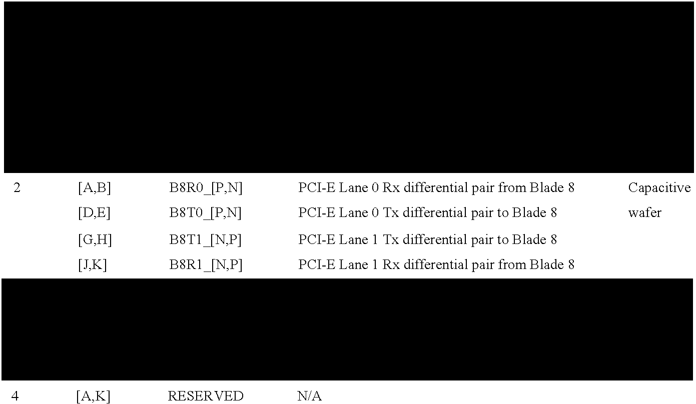

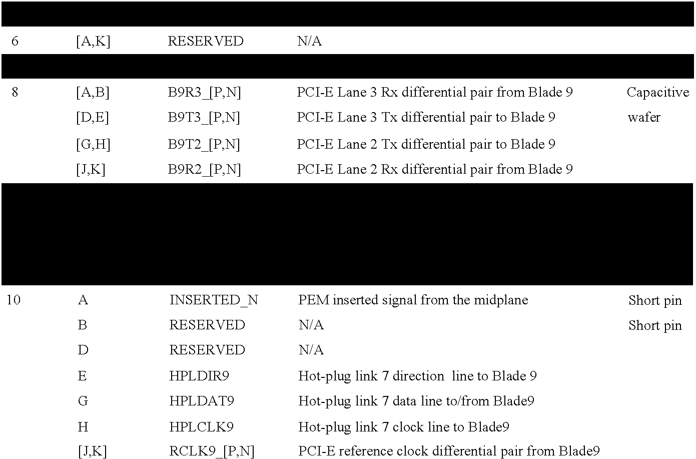

The Sun Blade 8000 Modular system makes extensive use of PCI-Express hot-plug in the overall product architecture. Hot-pluggable PCI-Express devices include the two PCI-E Express modules (NEM) resident in the rear of the chassis which are owned by each blade. Furthermore, the four PCI-Express Express modules (EMs) in the rear of the chassis each present what appears to each blade as a hot-plug PCI-E Express module. Thus, when an administrator wishes to perform a hot-plug operation on a NEM, the SC coordinates the hot-plug operation with all blades present in the chassis. Each blade sees its slice of the NEM in question as a card in a hot-plug capable slot.

The hot-plug hardware consists of the hot-plug register sets resident in the CK8-04 and IO-4, plus an FPGA and private hardware interface to the CK8-04 and IO-4. When an administrator initiates a hot-plug operation, the hot-plug FPGA and CK8-04/IO-4 will stimulate the BIOS-provided ACPI ASL routines via an SCI interrupt, which in turn stimulates the hardware to control clocks, indicators, and slot-power to effect the hot-plug operation. The Sun Blade 8000 Modular system blade also provides the capability for O/S native hot-plug by allowing the hot-plug events to be routed to the PCI_INTR[W] interrupt line. The default behavior of the hardware at boot is for events to generate SCI interrupts, but the O/S can switch over to using the PCI_INTR[W] interrupt line via a call to the ACPI OSC routine, indicating its native hot-plug capabilities.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. An apparatus, comprising:
a chassis;
a first plurality of bays in the chassis, wherein the first plurality of bays is adapted to receive and at least partially house a plurality of CPU modules, and wherein the first plurality of bays is accessible through a first side of the chassis;
a second plurality of bays in the chassis, wherein the second plurality of bays is adapted to receive and at least partially house a plurality of PCI-Express modules, and wherein the second plurality of bays is accessible through a second side of the chassis; and
a midplane board arranged to pass a PCI-Express signal between at least one of the plurality of CPU modules and at least one of the plurality of PCI-Express modules.

2. The apparatus of claim 1, wherein the plurality of CPU modules is operatively connected to the midplane board, and wherein the midplane board is operatively connected to the plurality of PCI-Express modules.

3. The apparatus of claim 1, wherein one of the plurality of CPU modules is operatively connected to two of the plurality of PCI-E Express modules.

4. The apparatus of claim 1, wherein the midplane board is further operatively connected to at least one Network Express module arranged to provide network I/O.

5. The apparatus of claim 1, further comprising:
a third plurality of bays in the chassis, wherein the third plurality of bays is adapted to receive and at least partially house at least one server I/O module, and wherein the third plurality of bays is accessible through the rear side of the chassis.

6. The apparatus of claim 1, further comprising:
a third plurality of bays in the chassis, wherein the third plurality of bays is adapted to receive and at least partially house at least one system controller module, and wherein the third plurality of bays is accessible through the rear side of the chassis.

7. The apparatus of claim 1, further comprising:
a third plurality of bays in the chassis, wherein the third plurality of bays is adapted to at least partially house a plurality of fans arranged to cool air within the chassis, and wherein the third plurality of bays accessible through the rear side of the chassis.

8. The apparatus of claim 1, further comprising:
at least one power supply unit accessible through the front side of the chassis; and
a power input accessible on the rear side of the chassis, the power input being operatively connected to the at least one power supply unit.

9. A blade server, comprising:
a plurality of blades retained within a chassis of the blade server, the plurality of blades being accessible through a front side of the chassis;
a midplane board arranged to pass PCI-Express signals;
a first PCI-Express connector arranged to connect at least one of the plurality of blades and the midplane board;
a plurality of PCI-Express modules retained in the chassis, the PCI-Express modules being accessible through a rear side of the chassis; and
a second PCI-Express connector arranged to connect the midplane board and at least one of the plurality of PCI-Express modules.

10. The blade server of claim 9, wherein one of the plurality of blades is mapped to two of the plurality of PCI-E Express modules.

11. The blade server of claim 9, wherein the midplane board is further operatively connected to at least one Network Express module arranged to provide network I/O.

12. The blade server of claim 9, further comprising:
at least one server I/O module retained within the chassis of the blade server, the at least one server I/O module being accessible through the rear side of the chassis.

13. The blade server of claim 9, further comprising:
at least one system controller module retained within the chassis of the blade server, the at least one system controller module being accessible through the rear side of the chassis.

14. The blade server of claim 9, further comprising:
a plurality of fans arranged to cool air within the blade server and retained within the chassis of the blade server, the plurality of fans being accessible through the rear side of the chassis.

15. The blade server of claim 9, further comprising:
at least one power supply unit accessible through the front side of the chassis, and
a power input accessible on the rear side of the chassis, the power input being operatively connected to the at least one power supply unit.

16. A method of performing computing operations, comprising:
receiving from a network a request to perform an operation;
performing the operation in response to the receiving; and
passing a PCI-Express signal over a midplane of a blade server dependent on the performing; and
passing the PCI-Express signal from the midplane to a PCI-Express module of the blade server connected to the network.

17. The method of claim 16, wherein the PCI-Express module is accessible through a rear side of a chassis of the blade server.

18. The method of claim 16, a blade of the blade server performing the operation, wherein the blade is accessible through a front side of a chassis of the blade server.

19. The method of claim 16, further comprising:
powering the blade server using a power supply accessible through a front side of a chassis of the blade server.

20. The method of claim 16, further comprising:
cooling the blade server using a plurality of fans accessible through a rear side of a chassis of the blade server.

21. A blade server, comprising:
a plurality of blades retained within a chassis of the blade server, the plurality of blades being accessible through a first side of the chassis;
a midplane board operatively connected to the plurality of blades and arranged to pass PCI-Express signals; and
a Network Express module operatively connected to the midplane board and retained in the chassis, the Network Express module being accessible through a second side of the chassis,
wherein the plurality of blades are operatively connectable to the Network Express module.

22. A blade server, comprising:
a plurality of blades; and
a plurality of redundant fans arranged to cool the plurality of blades, the plurality of redundant fans being positioned along a rear side of a chassis of the blade server,
wherein an air flow zone for cooling the plurality of blades is separate from an air flow zone for at least one of a power supply and I/O of the blade server.
